(19) United States
(12) Patent Application Publication
(10) Pub. No.: US 2010/0015755 A1
(43) Pub. Date: Jan. 21, 2010

(54) MANUFACTURING METHOD OF SEMICONDUCTOR MEMORY DEVICE

(75) Inventors: Yuichi Matsui, Kawasaki (JP); Takahiro Morikawa, Hachioji (JP)

Correspondence Address: MILES & STOCKBRIDGE PC, 1751 PINNACLE DRIVE, SUITE 500, MCLEAN, VA, 22102-3833, US

(73) Assignee: RENESAS TECHNOLOGY CORP., Tokyo (JP)

(21) Appl. No.: 12/524,049

(22) PCT Filed: Jan. 25, 2007
(86) PCT No.: PCT/JP2007/051202

§ 371 Date: Jul. 22, 2009

(51) Int. Cl. H01L 21/00; H01L 21/06

(52) U.S. Cl. 438/95; 438/102; 257/E21.001; 257/E21.068

(57) ABSTRACT

In a step of forming an InGeSbTe film which contains GeSbTe made of germanium (Ge), antimony (Sb) and tellurium (Te) as its base material and to which indium (In) is added, an InGeSbTe film is formed by sputtering on a semiconductor substrate while keeping a temperature of the semiconductor substrate between an in-situ crystallization temperature of GeSbTe serving as the base material and an in-situ crystallization temperature of InGeSbTe. As a result, it is possible to suppress the failure that the phase separation occurs in the InGeSbTe film during the following manufacturing process.

### TECHNICAL FIELD

The present invention relates to a manufacturing technique of a semiconductor memory device, and more particularly to a technique effectively applied to the manufacture of a phase change memory using a chalcogenide film for a memory layer.

### BACKGROUND ART

Information devices, electric home appliances, in-vehicle devices and others are mounted with a microcomputer for an embedded device, in which a flash memory for storing a program and data is embedded (memory-embedded microcomputer). In recent years, with the improvement in performance of these devices, the demands for improving the performance of the memory-embedded microcomputer have been increasing, and further improvement in the rewriting durability and the integration degree of the embedded flash memory has been demanded.

Furthermore, also in the DRAM which is a general-purpose memory, in order to satisfy the demand for higher integration, scaling-down of the memory cells has been advanced. However, the DRAM which stores information depending on the amount of charge accumulated in a capacitor has a problem that the storage capacity is reduced if the area of the capacitor is decreased. There is also a problem that the leakage current is increased if a dielectric material of the capacitor is thinned below a predetermined value. Up until now, the reduction of the area has been prevented by forming a capacitor in a deep trench or the like, but when the further scaling-down is to be promoted, the aspect ratio of the trench reaches the processing limit, and it becomes impossible to produce the device with good yield even if the leading-edge processing technique is fully used.

In this kind of environment, various new semiconductor memory elements such as a phase change memory utilizing the phase change of a chalcogenide material (Phase change RAM: PRAM), a MRAM (Magnetic RAM) utilizing the spin of a magnetic material, a molecular memory utilizing the oxidation-reduction of organic molecules and a RRAM (Resistance RAM) utilizing a material called strongly-correlated electron system have been developed in recent years. Among them, the phase change memory has attracted attention as a next-generation flash memory for a memory-embedded microcomputer and an alternative memory of the DRAM because of its characteristics that read/write can be performed at high speed, rewriting durability is high, and it is advantageous for higher integration.

In the phase change memory, by use of the reversible change of a chalcogenide film constituting a memory layer by heat between an amorphous state (high resistance) and a crystalline state (low resistance) having different electric resistances, the storage and readout are performed with taking the difference in the amount of current flowing in the film as the information of “0” and “1”. Since the multicomponent chalcogenide which is a material of the memory layer has already had a track record of being used as a material of a recording layer of optical discs such as CD-RW and DVD-RAM, it is characterized in that it can be handled more easily than the materials used in the above-described other semiconductor memory elements.

The sputtering method is used for forming a chalcogenide film on the surface of an optical disc and a semiconductor wafer. For example, the patent documents 1 to 6 described below disclose the techniques for forming a chalcogenide film by the sputtering method while controlling the substrate temperature.

Japanese Patent Application Laid-Open Publication No. 2006-156886 (Patent Document 1) discloses the technique for controlling the substrate temperature at the time of forming a chalcogenide film within a range from a room temperature to 150° C.

Japanese Patent Application Laid-Open Publication No. 2006-140395 (Patent Document 2) discloses the technique for controlling the substrate temperature at the time of forming a chalcogenide film within a narrow range around 100° C.

Japanese Patent Application Laid-Open Publication No. 2006-202823 (Patent Document 3) discloses the technique for controlling the substrate temperature at the time of forming a chalcogenide film within a range from 50° C. to 100° C.

Japanese Patent Application Laid-Open Publication No. 2006-45675 (Patent Document 4) discloses the technique for controlling the substrate temperature at the time of forming a chalcogenide film within a range from 100° C. to 350° C.

Japanese Patent Application Laid-Open Publication No. 2006-225390 (Patent Document 5) discloses the technique for controlling the substrate temperature at the time of forming a chalcogenide film within a range from 200° C. to 350° C.

Japanese Patent Application Publication No. 2000-509204 (Patent Document 6) discloses the technique for controlling the substrate temperature at the time of forming a chalcogenide film within a range from an ambient temperature to 300° C.

Patent Document 1: Japanese Patent Application Laid-Open Publication No. 2006-156886

Patent Document 2: Japanese Patent Application Laid-Open Publication No. 2006-140395

Patent Document 3: Japanese Patent Application Laid-Open Publication No. 2006-202823

Patent Document 4: Japanese Patent Application Laid-Open Publication No. 2006-45675

Patent Document 5: Japanese Patent Application Laid-Open Publication No. 2006-225390

Patent Document 6: Japanese Patent Application Publication No. 2000-509204

### DISCLOSURE OF THE INVENTION

### Problem to be Solved by the Invention

When a semiconductor chip is mounted on a wiring board or others, it is exposed to a high temperature environment higher than its operation temperature in, for example, the soldering process at 250° C. for several minutes and the pressure bonding process at 180° C. for several hours. In the case of the memory-embedded microcomputer, for example, it is generally mounted after a program is stored in a memory part, and therefore, it is necessary to ensure the data retention properties even under the temperature environment higher than the operation temperature to some extent so that the data is not deleted by the thermal load in the mounting process.

However, with regard to chalcogenide which is a material of a memory layer of a phase change memory, its amorphous state having high resistance is a metastable phase. Therefore, there is a problem that its crystallization (resistance reduction) is rapidly advanced under the high temperature environment. For example, the inventors of the present invention have studied the use of a three-component chalcogenide (GeSbTe) made of Ge (germanium), Sb (antimony) and Te (tellurium) as a material of a memory layer of a phase change memory. However, it has been found that this three-component chalcogenide is not suitable for practical use because a Ge₂Sb₂Te₅ film is changed from an amorphous state to a crystalline state in only several seconds and the data is lost when it is exposed to a high temperature environment of 250° C.

Therefore, in order to realize a phase change memory that exercises the good data retention properties even under the high temperature environment, the inventors of the present invention have been studying the use of an InGeSbTe film obtained by adding In (indium) to a GeSbTe film as a material of a memory layer having higher heat resistance than the GeSbTe film described above. For example, since an In₂₀Ge₁₅Sb₁₀Te₅₅ film keeps an amorphous state at least for several minutes even when it is exposed to the high temperature environment of 250° C., the data is not lost in the soldering process and the pressure bonding process.

However, when InGeSbTe is used for a memory layer, another problem resulting from a material composition is caused in the manufacturing process of a phase change memory. In the manufacturing process of a phase change memory, the heat treatment of at least 300° C. or higher is necessary in the wiring process after the formation of the memory layer. Since GeSbTe to which In is added does not have a stable composition, the phase separation of In₂Te₃ is likely to occur due to the heat in the wiring process. The occurrence of the phase separation causes the variation in electrical properties and the reduction in the number of rewrite times. Accordingly, means for manufacturing a phase change memory without causing the phase separation of InGeSbTe is required. Note that, although In is mentioned as an additive element in the description above, the same problem is caused if an additive element has a composition that does not make a stable composition with GeSbTe.

An object of the present invention is to provide a technique capable of suppressing the phase separation of a chalcogenide film, in particular, GeSbTe to which In is added during the manufacturing process.

The above and other objects and novel characteristics of the present invention will be apparent from the description of this specification and the accompanying drawings.

### Means for Solving the Problems

The typical ones of the inventions disclosed in this application will be briefly described as follows.

In one invention of the present application, in a step of forming an InGeSbTe film which contains GeSbTe made of Ge, Sb and Te as a base material and to which In is added, the InGeSbTe film is formed on a semiconductor substrate by sputtering while keeping a temperature of the semiconductor substrate within a range between an in-situ crystallization temperature of GeSbTe serving as a base material and an in-situ crystallization temperature of InGeSbTe.

### EFFECT OF THE INVENTION

The effects obtained by typical embodiments of the inventions disclosed in this application will be briefly described below.

Since a high-quality amorphous InGeSbTe film can be formed when an InGeSbTe film constituting a memory layer is deposited by the sputtering method, the failure that the phase separation occurs in an InGeSbTe film during the manufacturing process of a phase change memory can be suppressed. Consequently, it is possible to manufacture the phase change memory that exercises the good data retention properties with good yield even under the high temperature environment.

### BRIEF DESCRIPTION OF THE DRAWINGS

FIG. 1 is a cross-sectional view showing a manufacturing method of a semiconductor memory device according to an embodiment of the present invention;

FIG. 2 is a cross-sectional view showing the manufacturing method of the semiconductor memory device continued from FIG. 1;

FIG. 3 is a cross-sectional view showing the manufacturing method of the semiconductor memory device continued from FIG. 2;

FIG. 4 is a cross-sectional view showing the manufacturing method of the semiconductor memory device continued from FIG. 3;

FIG. 5 is a cross-sectional view showing the manufacturing method of the semiconductor memory device continued from FIG. 4;

FIG. 6 is a cross-sectional view showing the manufacturing method of the semiconductor memory device continued from FIG. 5;

FIG. 7 is a cross-sectional view showing the manufacturing method of the semiconductor memory device continued from FIG. 6;

FIG. 8 is a cross-sectional view showing the principal part of the manufacturing method of the semiconductor memory device continued from FIG. 7;

FIG. 9 is a cross-sectional view showing the principal part of the manufacturing method of the semiconductor memory device continued from FIG. 8;

FIG. 10 is a cross-sectional view showing the principal part of the manufacturing method of the semiconductor memory device continued from FIG. 9;

FIG. 11 is a cross-sectional view showing the principal part of the manufacturing method of the semiconductor memory device continued from FIG. 10;

FIG. 12 is a cross-sectional view showing the principal part of the manufacturing method of the semiconductor memory device continued from FIG. 11;

FIG. 13 is a cross-sectional view showing the principal part of the manufacturing method of the semiconductor memory device continued from FIG. 12;

FIG. 14 is a cross-sectional view showing the principal part of the manufacturing method of the semiconductor memory device continued from FIG. 13;

FIG. 15 is a cross-sectional view showing the manufacturing method of the semiconductor memory device continued from FIG. 14;

FIG. 16 is an explanatory diagram showing dependency of the retention time on In concentration;

FIG. 17 is a graph for comparing standard deviations of sheet resistance of In₂₀Ge₁₅Sb₁₀Te₅₅ films deposited at various substrate temperatures and subjected to a post heat treatment at 300° C.;

FIG. 18 is a graph showing dependency of the in-situ crystallization temperature of InGeSbTe on In concentration;

FIG. 19 are graphs showing a result of comparison of distributions of reset voltage of phase change memories using the In₂₀Ge₁₅Sb₁₀Te₅₅ films deposited at 50° C. (FIG. 19A), 180° C. (FIG. 19B) and 240° C. (FIG. 19C); and

FIG. 20 is a graph showing a temperature dependency of electric conductivity of a ZnGeSbTe film heated from an amorphous state.

### BEST MODE FOR CARRYING OUT THE INVENTION

Hereinafter, embodiments of the present invention will be described in detail with reference to the accompanying drawings. Note that components having the same function are denoted by the same reference numbers throughout the drawings for describing the embodiments, and the repetitive description thereof will be omitted. Also, the composition formula for the three-component chalcogenide made of Ge, Sb and Te of the present invention is GeₓSb_{y}Te_{z}, and when the composition ratios x, y and z are arbitrary, the composition formula is expressed as GeSbTe in an abbreviated manner in some cases. Further, the same is true of the four or more component chalcogenide. For example, the composition formula for the four-component chalcogenide made of Ge, Sb, Te and In is In_{w}GeₓSb_{y}Te_{z}, and when the composition ratios x, y, z and w are arbitrary, the composition formula is expressed as InGeSbTe in an abbreviated manner in some cases.

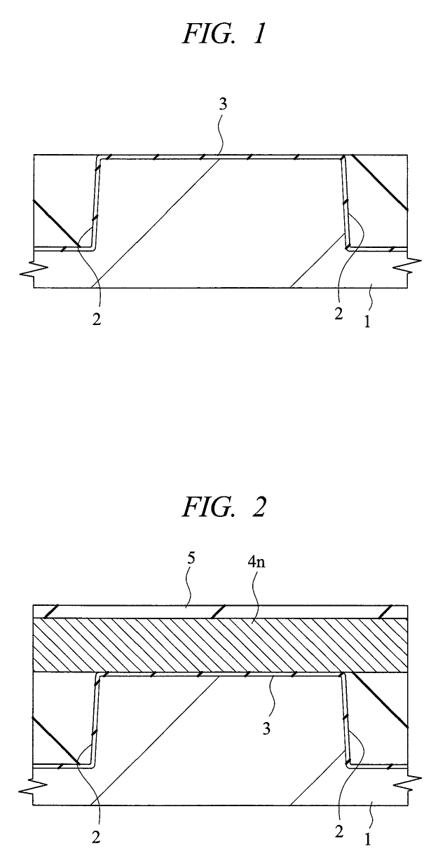

The manufacturing method of a phase change memory according to the present embodiment will be described in order of steps with reference to FIG. 1 to FIG. 15. First, as shown in FIG. 1, a p type semiconductor substrate (hereinafter, referred to as substrate) 1 made of single crystal silicon with a plane direction (100) is prepared. It does not matter if an SOI (Silicon On Insulator) substrate, a single crystal Ge substrate, GOI (Ge On Insulator) substrate or a strained silicon substrate obtained by applying straining stress to crystal is used as the substrate 1 instead of the single crystal silicon substrate.

Next, after openings are formed in the substrate 1 by dry etching using a silicon nitride film as a mask, a silicon oxide film is embedded in the openings. Subsequently, a surface of the substrate 1 is planarized by CMP (Chemical Mechanical Polishing) method to form element isolation trenches 2, thereby defining active regions in which transistors are formed.

Next, ion implantation and extension heat treatment for adjusting the substrate concentration and ion implantation and activation heat treatment for adjusting threshold voltage are carried out. Subsequently, after cleaning the surface of the substrate 1 with diluted hydrofluoric acid solution, the thermal oxidation treatment is performed, thereby forming a gate insulating film 3 made of a silicon oxide film with a thickness of about 3 nm on the surface of the substrate 1. It does not matter if an insulating film other than a silicon oxide film, for example, a silicon oxynitride film (SiON film) obtained through the surface nitriding process, a high-k film obtained by performing oxidizing or nitriding process to various kinds of metals, or a stacked film of these films is used as the gate insulating film 3.

Next, as shown in FIG. 2, after depositing a polycrystalline silicon film 4n on the gate insulating film 3 by the CVD (Chemical Vapor Deposition) method, a cap insulating film 5 made of a silicon oxide film is deposited on the polycrystalline silicon film 4n by the CVD method. Phosphorus or arsenic is implanted into the polycrystalline silicon film 4n during its formation so as to change the conductivity type thereof to an n type. The polycrystalline silicon film 4n is to be a gate electrode material, but it does not matter if a gate electrode material other than the polycrystalline silicon film 4n, for example, a silicide film or a metal film is used.

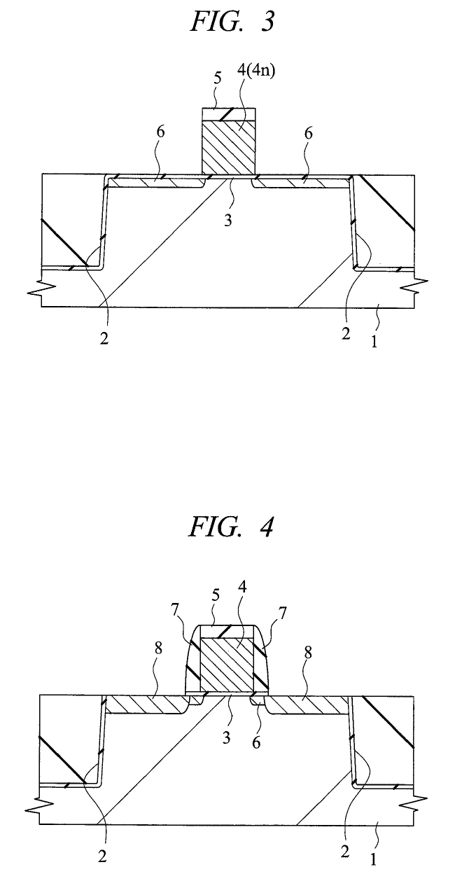

Next, as shown in FIG. 3, the cap insulating film 5 and the polycrystalline silicon film 4n are patterned by the dry etching using a photoresist film as a mask to firm a gate electrode 4, and then, phosphorus or arsenic is ion-implanted into the substrate 1 to form n⁻ type diffusion layers 6.

Next, as shown in FIG. 4, a silicon nitride film deposited on the substrate 1 by the CVD method is anisotropically etched to form sidewall spacers 7 on side walls of the gate electrode 4, and then, after ion-implanting arsenic into the substrate 1, the activation heat treatment is carried out, thereby forming n⁺ diffusion layers 8 constituting a source and a drain. Through the process described above, an n channel type MISFET for memory cell selection is completed.

Alternatively, the above-described gate electrode 4 can be formed through a dummy gate process. In the dummy gate process, a conductive film (polycrystalline silicon film or the like) for a dummy gate deposited on a gate insulating film is first processed to form a dummy gate electrode, and then, after forming a source and a drain, the gate insulating film and the dummy gate electrode are removed. Next, after a gate insulating film is formed again and a conductive film (metal film or the like) for a gate is deposited thereon, this conductive film is processed to form a gate electrode. When the dummy gate process is employed, the gate insulating film can be formed by using a high-k material having a low crystallization temperature.

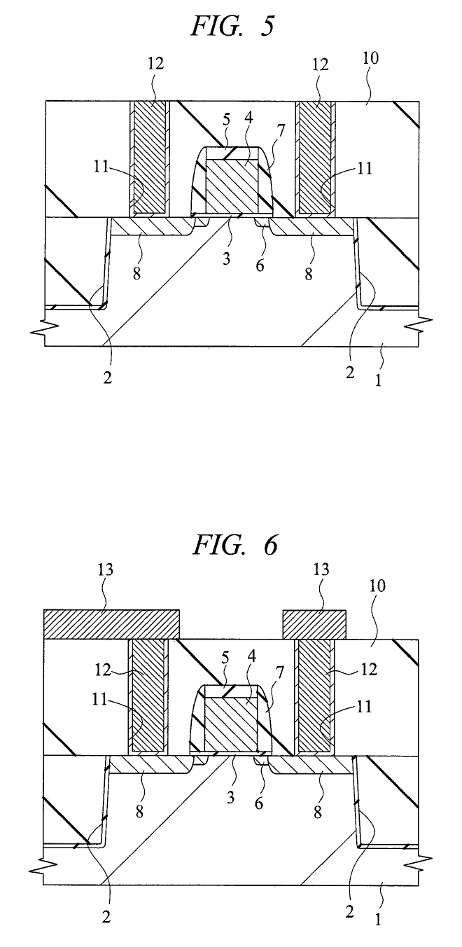

Next, as shown in FIG. 5, after an interlayer insulating film 10 made of a silicon oxide film is formed on the substrate 1 by the CVD method and the surface thereof is planarized by the CMP method, contact holes 11 are formed in the interlayer insulating film 10 positioned on the n⁺ diffusion layers 8 (source, drain), and plugs 12 are formed inside the contact holes 11. The plug 12 assumes a role of electrically connecting a memory layer to be formed on the interlayer insulating film 10 in the next step and the underlying MISFET for memory cell selection, and it is formed of, for example, a stacked film of a TiN (titanium nitride) film and a W (tungsten) film.

Next, as shown in FIG. 6, a first-layer wiring 13 is formed on the interlayer insulating film 10. For example, the wiring 13 is formed by depositing a W film on the interlayer insulating film 10 by the sputtering method, and then patterning this W film by the dry etching using a photoresist film as a mask. The wiring 13 is electrically connected to the n⁺ diffusion layer 8 via the plug 12 inside the contact hole 11.

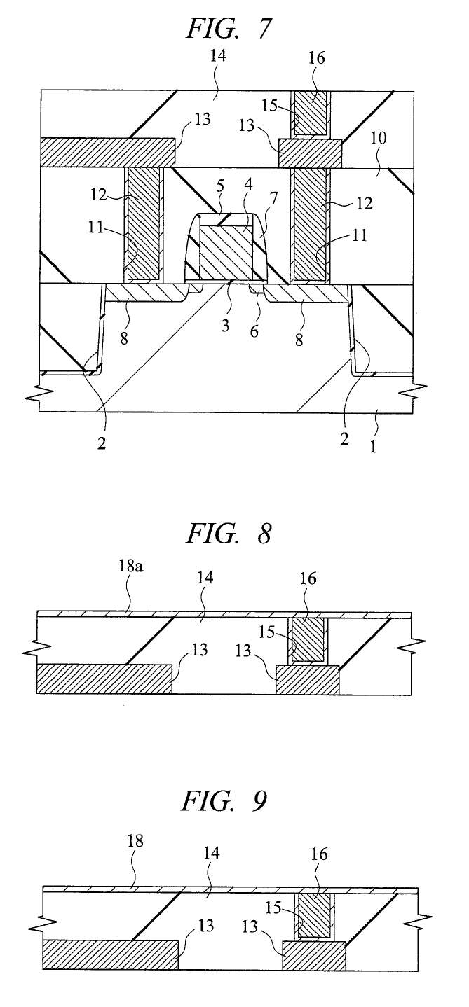

Next, as shown in FIG. 7, after an interlayer insulating film 14 made of a silicon oxide film is deposited on the substrate 1 by the CVD method and the surface thereof is planarized by the CMP method, a through hole 15 and a plug 16 are formed in the interlayer insulating film 14 positioned on the wiring 13 through the same method as that of forming the contact hole 11 and the plug 12 described above.

Next, by the sputtering performed with using a Ta metal target in an argon atmosphere, a Ta (tantalum) film 18a is formed on the surface of the substrate 1 (wafer) (FIG. 8). Next, by the radical oxidation to the Ta film 18a, an interface layer 18 made of a tantalum oxide (Ta₂O₅) film is formed (FIG. 9). The interface layer 18 assumes both a role as an adhesive layer for preventing the exfoliation between the interlayer insulating film 14 and the memory layer material (chalcogenide film 19a) formed thereon and a role as a heat resistance layer for suppressing the escape of Joule heat from the memory layer to the plugs 16 at the time of the information rewriting. The material of the interface layer 18 is not limited to tantalum oxide, and titanium oxide, zirconium oxide, hafnium oxide, niobium oxide, chromium oxide, cobalt oxide, nickel oxide or others may be used. Note that illustrations of the part below the wirings 13 are omitted in FIGS. 8 to 14 so as to make the drawings easy to see.

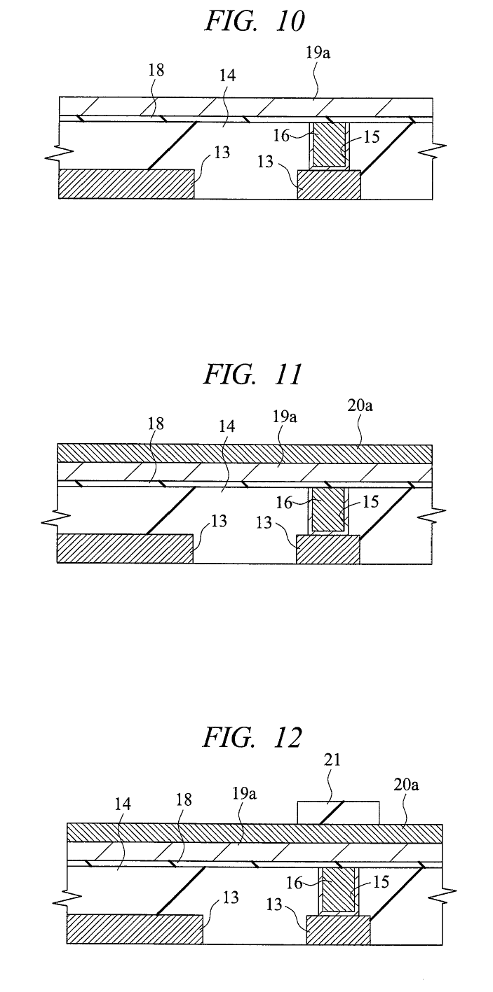

Next, when InGeSbTe is used for a memory layer, the chalcogenide film 19a with a thickness of about 50 nm is formed on the interface layer 18 by performing the sputtering with using a GeSbTe target to which 20 atomic % of In is added in an argon atmosphere while keeping the temperature of the substrate 1 within the range between the in-situ crystallization temperature of GeSbTe serving as a base material and the in-situ crystallization temperature of InGeSbTe (FIG. 10). Although it depends on the sputtering conditions, the in-situ crystallization temperature in the case of using Ge₂Te₂Sb₅ as a base material is about 100° C. and the in-situ crystallization temperature in the case where InGeSbTe is In₂₀Ge₁₅Sb₁₀Te₅₅ is about 240° C. Therefore, the chalcogenide film 19a is formed while keeping the temperature of the substrate 1 at, for example, 180° C. Note that the in-situ crystallization means the crystallization during the film formation.

In the case of the sputtering using a GeSbTe target to which 20 atomic % of In is added, the chalcogenide film 19a is made of InGeSbTe having the In concentration of 20 atomic % (In₂₀Ge₁₅Sb₁₀Te₅₅). Note that, for adjusting the phase change temperature of the memory layer made of the chalcogenide film 19a, for example, the sputtering in the atmosphere containing oxygen (O) and nitrogen (N) together with argon may be performed. Furthermore, it is also possible to form the chalcogenide film 19a by the simultaneous sputtering using various types of targets.

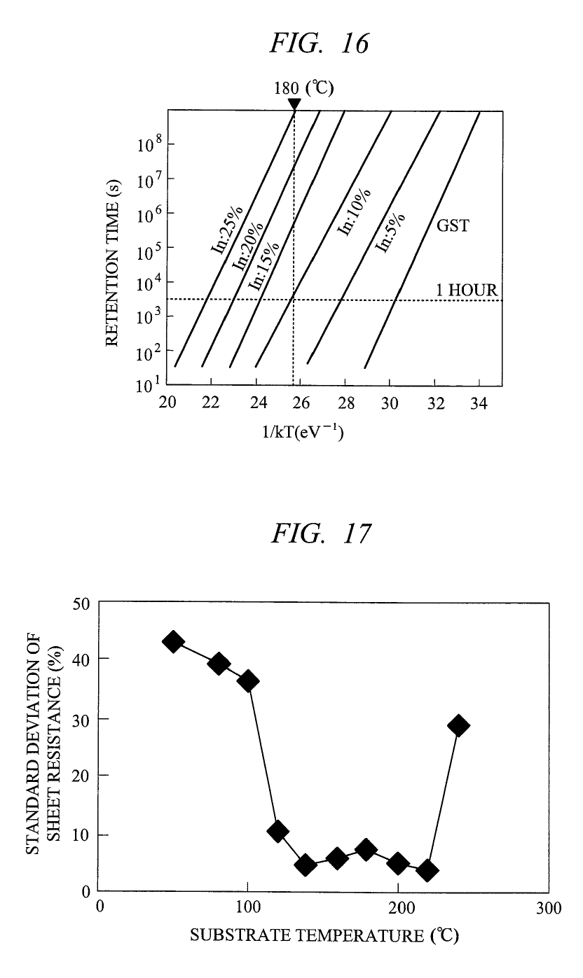

Furthermore, although the In concentration in the chalcogenide film 19a is set to 20 atomic % in the present embodiment, it is sufficient if the concentration is 10 atomic % or higher. This point will be described below with reference to FIG. 16. FIG. 16 is an explanatory diagram showing the dependency of the retention time on the In concentration. The retention time mentioned here is the time to reduce the resistance to half while keeping a chalcogenide material in an amorphous state at a constant temperature. Also, GST in the diagram shows Ge₂Sb₂Te₅.

As shown in FIG. 16, it can be understood that the retention time is increased when the In concentration is increased. In order to prevent the data from being deleted even under the thermal load at 180° C. for 1 hour, 10% or higher of In has to be added. Accordingly, the chalcogenide film 19a preferably has the In concentration of 10 atomic % or higher. When the chalcogenide film 19a whose In concentration is 10 atomic % is to be formed, for example, it can be formed by performing the sputtering in an argon atmosphere with using a GeSbTe target to which 10 atomic % of In is added.

Further, in the present embodiment, the sputtering method is employed as a method for forming the chalcogenide film 19a. The CVD method and the sol-gel method can also be employed as other methods for forming the chalcogenide film 19a. In the case of the CVD method, the substrate temperature has to be increased so as to sufficiently decompose the material. Therefore, it seems difficult to control the substrate temperature to the temperature higher than the crystallization temperature of a chalcogenide film serving as a base material and lower than the crystallization temperature of the chalcogenide film containing an additive element like in the present invention. Also, in the sol-gel method, it seems difficult to control the thickness of the film to be formed. Meanwhile, since the substrate temperature can be arbitrarily chosen in the sputtering method, the sputtering method is desirably used in the embodiment of the present invention.

Subsequently, a W film 20a is deposited on the chalcogenide film 19a by performing the sputtering using a W target in an argon atmosphere (FIG. 11).

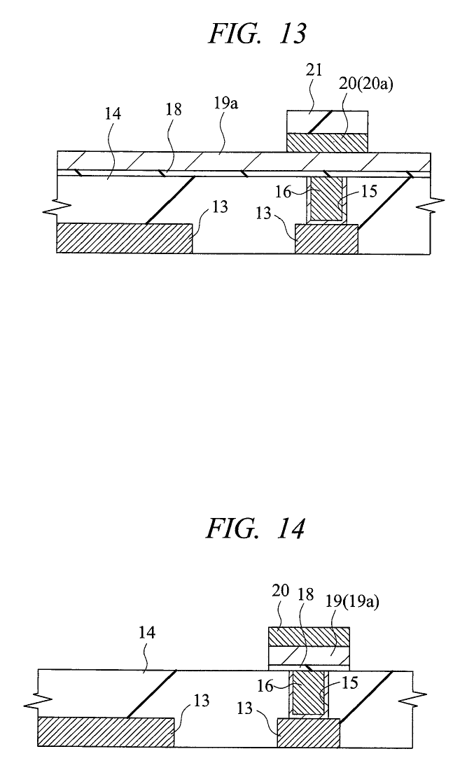

Next, as shown in FIG. 12, after depositing a silicon oxide film on the W film 20a by the CVD method, this silicon oxide film is patterned by the dry etching using a photoresist film as a mask, thereby forming a hard mask 21. Subsequently, as shown in FIG. 13, the W film 20a is patterned by the dry etching using the hard mask 21 as a mask, thereby forming an upper electrode 20.

Next, after removing the hard mask 21, as shown in FIG. 14, the chalcogenide film 19a is patterned by the dry etching using the upper electrode 20 as a mask, and then, the interface layer 18 below the chalcogenide film 19a is patterned. Through the process described above, the memory layer 19 made of the chalcogenide film 19a is formed on the interlayer insulating film 14. This memory layer 19 stores information by the difference in an electrical resistance value caused by the phase change.

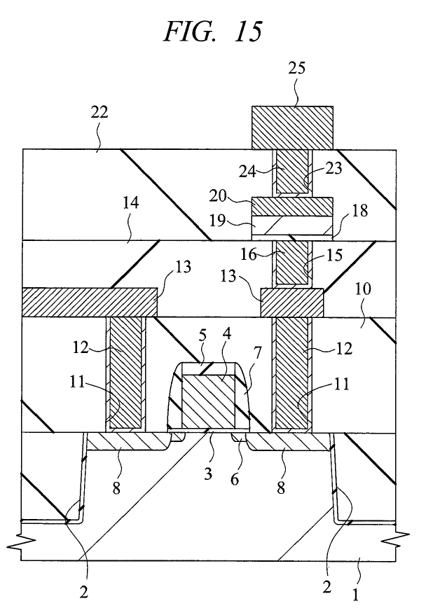

Next, as shown in FIG. 15, after an interlayer insulating film 22 made of a silicon oxide film is deposited on the upper electrode 20 by the CVD method and the surface thereof is planarized by the CMP method, a through hole 23 and a plug 24 are formed in the interlayer insulating film 22 on the upper electrode 20 through the same method as that of forming the contact hole 15 and the plug 16 described above. Next, a second-layer wiring 25 is formed on the interlayer insulating film 22 through the same method as that of forming the first-layer wiring 13. The wiring 25 is electrically connected to the upper electrode 20 via the plug 24 inside the through hole 23.

Through the process described above, the phase change memory (semiconductor memory device) is almost completed. In the steps of forming the interlayer insulating film 22, the plug 24 and the wiring 25 in the manufacturing process thereof, the heat treatment of 300° C. or higher is necessary. However, since the failure that the phase separation occurs in an InGeSbTe film during the manufacturing process of a phase change memory can be suppressed by forming the chalcogenide film 19a while keeping the temperature of the substrate 1 within the range between the in-situ crystallization temperature of GeSbTe serving as the base material and the in-situ crystallization temperature of InGeSbTe in the step of forming the chalcogenide film 19a, the phase change memory with highly uniform electrical characteristics can be obtained. This point will be described below in detail.

First, the desired substrate temperature in the step of forming the chalcogenide film 19a of the present embodiment will be described. Here, the In₂₀Ge₁₅Sb₁₀Te₅₅ films are deposited at various substrate temperatures, and then, the post heat treatment at 300° C. is carried out. FIG. 17 shows a graph for comparing the standard deviations of sheet resistance. It can be understood that when the substrate temperature is 100° C. or lower and 240° C. or higher, the standard deviation is large, in other words, the variation is large.

The reason why the variation becomes large when the substrate temperature is 100° C. or lower can be explained as follows. That is, since the crystallization temperature of a Ge₂Sb₂Te₅ film which is a base material of the In₂₀Ge₁₅Sb₁₀Te₅₅ film obtained by adding In to GeSbTe is about 100° C., when the In₂₀Ge₁₅Sb₁₀Te₅₅ film is formed at the substrate temperature higher than 100° C., crystal nucleus is created in the film. As a result, the In₂₀Ge₁₅Sb₁₀Te₅₅ film becomes a high-quality amorphous film, and the variation in resistance is reduced. On the other hand, when the In₂₀Ge₁₅Sb₁₀Te₅₅ film is formed at the substrate temperature of 100° C. or lower, defects in the film are increased and the variation in resistance is increased.

Here, the crystallization temperature of GeSbTe used as a base material changes depending on its composition. For example, according to the non-patent document (Journal of Applied Physics, Vol. 69, pp. 2849-2856 (1991)), the crystallization temperature of GeSb₄Te₇ is 117° C., that of GeSb₂Te₄ is 135° C. and that of Ge₂Sb₂Te₅ is 143° C. However, since the crystallization temperature depends on pressure and time, it changes depending on a structure and an atmosphere to some extent. Further, the crystallization temperatures described above are temperatures at which the amorphous state is changed to the crystalline state by the post heat treatment, and the crystallization temperature in the present invention indicates the temperature at which the in-situ crystallization occurs during the film formation. Since the in-situ crystallization temperature is generally lower than the crystallization temperature by the post heat treatment by about 40 to 50° C., it is reasonable to think that, for example, the crystallization temperature of GeSb₄Te₇ is about 70° C., that of GeSb₂Te₄ is about 90° C. and that of Ge₂Sb₂Te5 is about 100° C.

The reason why the variation becomes large when the substrate temperature is 240° C. or higher can be explained as follows. That is, since the crystallization temperature of an In₂₀Ge₁₅Sb₁₀Te₅₅ film is about 240° C., the in-situ crystallization occurs when the In₂₀Ge₁₅Sb₁₀Te₅₅ film is formed at the substrate temperature higher than 240° C. In this case, since the In₂₀Ge₁₅Sb₁₀Te₅₅ film does not have a stable composition, atoms move with the crystallization on a surface so as to take a more stable structure in terms of energy, so that the variation in composition is locally caused in the film. The inventors of the present invention confirmed the phase separation of In₂Te₃ after the post heat treatment. When the phase separation occurs, the variation in resistance is increased.

The phase separation mentioned here was confirmed in the following manner. That is, a silicon oxide film with a thickness of about 100 nm was formed on a silicon substrate, and an In₂₀Ge₁₅Sb₁₀Te₅₅ film was deposited at a substrate temperature of 240° C. by using the sputtering method. Then, the post heat treatment was carried out for 30 minutes at 300° C. in a nitrogen atmosphere, and the crystal structure was analyzed by using the X-ray diffraction method. As a result, the appearance of diffraction lines resulting from In₂Te₃ was confirmed in addition to diffraction lines resulting from InGeSbTe crystallized to a FCC (Face Centered Cubic) structure. This shows that the phase separation of the In₂₀Ge₁₅Sb₁₀Te₅₅ film occurs by the heat treatment. On the other hand, in the case of the In₂₀Ge₁₅Sb₁₀Te₅₅ film deposited at the substrate temperature of 180° C., diffraction lines resulting from InGeSbTe with the FCC structure after the heat treatment at 300° C. were confirmed, but diffraction lines resulting from In₂Te₃ were not observed. This shows that the phase separation can be suppressed by controlling the substrate temperature in the deposition.

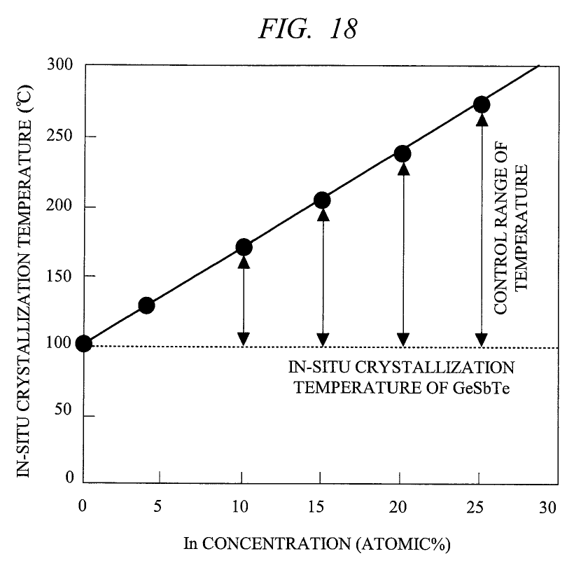

When summarized, the substrate temperature at the time of forming InGeSbTe obtained by adding In to GeSbTe serving as a base material is controlled to the temperature higher than the crystallization temperature of GeSbTe serving as the base material and lower than the crystallization temperature of InGeSbTe in the present embodiment. FIG. 18 shows dependency of the in-situ crystallization temperature on In concentration. As shown in FIG. 18, it can be understood that the crystallization temperature increases when the In concentration is increased. To control the substrate temperature at the time of forming a film to the temperature higher than the crystallization temperature of a GeSbTe film serving as the base material and lower than the crystallization temperature of a GeSbTe film to which In is added means that the substrate temperature is controlled within the ranges shown by arrows in FIG. 18. For example, when the In concentration is 20 atomic %, the substrate temperature should be controlled within the range from 100° C. to 240° C.

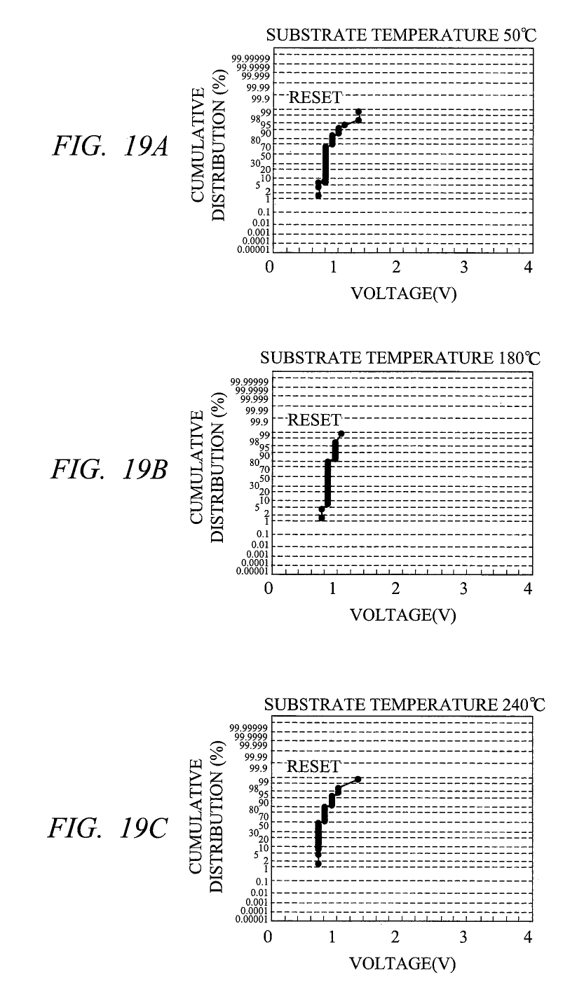

FIG. 19 shows the result of comparison of distributions of reset voltage of phase change memories using the In₂₀Ge₁₅Sb₁₀Te₅₅ films deposited at various substrate temperatures, in which FIG. 19A to FIG. 19C are distribution charts of the reset voltage of the phase change memories using the In₂₀Ge₁₅Sb₁₀Te₅₅ films deposited at 50° C., 180° C. and 240° C., respectively. The reset voltage is the voltage necessary for turning the In₂₀Ge₁₅Sb₁₀Te₅₅ film into an amorphous state (increasing the resistance). The graph of FIG. 19 is shown by the cumulative distribution, in which the smaller the gradient becomes, the larger the variation becomes. It can be understood that the variation in reset voltage is small at the substrate temperature of 180° C. compared with the cases of the substrate temperatures of 50° C. and 240° C. This is probably because since the variation in resistance in the crystalline state is small as shown in FIG. 17 when the In₂₀Ge₁₅Sb₁₀Te₅₅ film is formed at 180° C., the variation in voltage necessary for the reset is reduced.

As described above, in the present embodiment, the high-quality amorphous InGeSbTe film is formed by appropriately controlling the substrate temperature at the time of depositing the chalcogenide film 19a by the sputtering method. Therefore, the phase separation of the InGeSbTe film during the manufacturing process of the phase change memory after the deposition can be suppressed, and the phase change memory with highly uniform electrical characteristics can be obtained.

Consequently, the phase change memory which is provided with the memory layer 19 made of the chalcogenide film 19a with a high heat resistance and exercises the good data retention properties even under the high temperature environment can be manufactured with good yield.

In the foregoing, the invention made by the inventors of the present invention has been concretely described based on the embodiments. However, it is needless to say that the present invention is not limited to the foregoing embodiments and various modifications and alterations can be made within the scope of the present invention.

One kind of additive element (In) is used in the embodiment described above, but since the same problems are caused if the composition does not make a stable composition with GeSbTe even when a plurality of additive elements are used, the technique of the present invention can be applied. For example, the present invention may be applied to a chalcogenide film to which two or more kinds of elements selected from group 3 to 13 elements (desirably from group 9 to 13 elements) are added, or the present invention may be applied to a chalcogenide film to which oxygen and nitrogen are added in addition to one or more kinds of elements selected from group 3 to 13 elements (desirably from group 9 to 13 elements).

For example, in the case where one or more kinds of elements selected from group 3 to 13 elements are used, MGeSbTe (M is an additive element) does not have a stable composition, and therefore, the crystal containing the additive element (M) is phase-separated in some cases due to the heat in the wiring process. Therefore, when MGeSbTe is applied to a memory layer, by applying the technique of the present invention in which a MGeSbTe film is formed while keeping the temperature of a semiconductor substrate within a range between the in-situ crystallization temperature of GeSbTe and the in-situ crystallization temperature of MGeSbTe, the same effects as described in the embodiment above can be achieved.

Further, at least one of more kinds of additive elements selected from group 9 to 13 elements, for example, In (indium), Zn (zinc), Co (cobalt) and Ag (silver) are easily mixed with GeSbTe because their ion radii are close to those of Ge, Sb and Te of GeSbTe serving as a base material. Therefore, the chalcogenide film to which one or more kinds of elements selected from group 9 to 13 elements are added is easily applied to the memory layer.

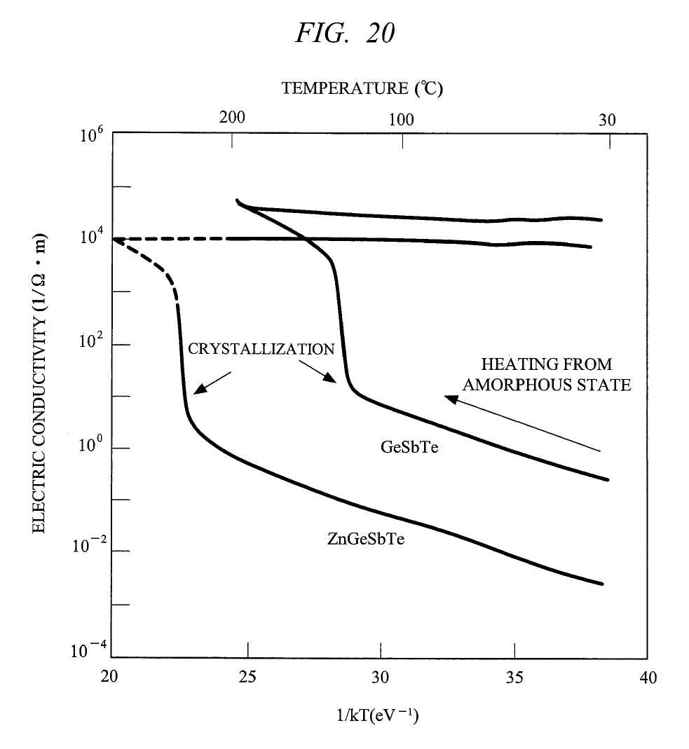

For example, also when Zn is added to GeSbTe serving as a base material, the same effect as that of the above-described embodiment in which In is added can be achieved. FIG. 20 shows the temperature dependency of electric conductivity of a ZnGeSbTe film heated from an amorphous state in comparison to GeSbTe. As shown in FIG. 20, when Zn is added to a GeSbTe film, the crystallization temperature (temperature at which the electric conductivity rapidly increases) is improved to about 100° C. In other words, when a ZnGeSbTe film constituting a memory layer is formed, if the semiconductor substrate temperature is kept between the in-situ crystallization temperature of GeSbTe serving as the base material and the in-situ crystallization temperature of ZnGeSbTe, the variation in resistance can be suppressed.

Further, in the above-described embodiment, the InGeSbTe film is formed while keeping the temperature of a semiconductor substrate between 100° C. at which GeSbTe serving as a base material is in-situ crystallized and 240° C. at which InGeSbTe is in-situ crystallized, but the range of the substrate temperature is not limited to this. That is, when a MGeSbTe film (M is an additive element) is used, any temperature range can be used as long as the range is higher than the in-situ crystallization temperature of GeSbTe (different depending on compositions of Ge, Sb and Te) serving as the base material and lower than the in-situ crystallization temperature of MGeSbTe (different depending on the additive element and composition).

### INDUSTRIAL APPLICABILITY

The present invention can be applied to the manufacture of a phase change memory using a chalcogenide film for a memory layer.

1. A manufacturing method of a semiconductor memory device, comprising a step of forming a memory layer storing information by a difference in an electrical resistance value caused by a phase change on a semiconductor substrate,
wherein the memory layer is made of a chalcogenide film which contains germanium, antimony and tellurium as its base material and to which at least one or more kinds of elements selected from group 3 to 13 elements are added, and
the chalcogenide film in an amorphous state is formed while keeping a temperature of the semiconductor substrate between a first temperature at which the base material is in-situ crystallized and a second temperature at which the chalcogenide film is in-situ crystallized.

2. The manufacturing method of a semiconductor memory device according to claim 1,
wherein the chalcogenide film is formed by adding at least one or more kinds of elements selected from group 9 to 13 elements to the base material.

3. The manufacturing method of a semiconductor memory device according to claim 1,
wherein the chalcogenide film is formed by adding at least one or more kinds of elements selected from indium, zinc, cobalt and silver to the base material.

4. A manufacturing method of a semiconductor memory device, comprising a step of forming a memory layer storing information by a difference in an electrical resistance value caused by a phase change on a semiconductor substrate,
wherein the memory layer is made of a chalcogenide film which contains germanium, antimony and tellurium as its base material and to which indium is added, and
the chalcogenide film in an amorphous state is formed while keeping a temperature of the semiconductor substrate between a first temperature at which the base material is in-situ crystallized and a second temperature at which the chalcogenide film is in-situ crystallized.

5. The manufacturing method of a semiconductor memory device according to claim 4,
wherein a concentration of the indium constituting the chalcogenide film is 10 atomic % or higher.

6. The manufacturing method of a semiconductor memory device according to claim 4,
wherein the chalcogenide film is formed by using a sputtering method.

7. The manufacturing method of a semiconductor memory device according to claim 4,
wherein the first temperature is 100° C. and the second temperature is 240° C.
